(19) United States
(12) Patent Application Publication
(10) Pub. No.: US 2026/0096438 A1
(43) Pub. Date: Apr. 2, 2026

(54) SEMICONDUCTOR PACKAGE WITH A CIRCUIT COMPONENT EMBEDDED IN A PACKAGING SUBSTRATE

(71) Applicant: TEXAS INSTRUMENTS INCORPORATED, DALLAS, TX (US)

(72) Inventors: HARSHPREET SINGH PHULL BAKSHI, DALLAS, TX (US); YAO YU, SAN JOSE, CA (US); RAJEN MANICON MURUGAN, Dallas, TX (US); JIE CHEN, Plano, TX (US); SYLVESTER ANKAMAH-KUSI, McKinney, TX (US)

(21) Appl. No.: 18/901,874

(22) Filed: Sep. 30, 2024

(51) Int. Cl. H01L 23/66; H01L 21/304; H01L 23/00; H01L 23/31; H01L 23/498

(52) U.S. Cl. CPC H10W 44/20; H10P 52/00; H10W 70/685; H10W 74/114; H10W 44/241; H10W 90/724

(57) ABSTRACT

A semiconductor device includes a die and a coreless embedded trace substrate (ETS). The die has an embedded circuit. The die can include ports on a surface of the die coupled to the embedded circuit of the die. The coreless ETS can underlie the die. The ETS can include a cavity having circuit components embedded in the cavity, ports on a surface of the ETS coupled to the circuit components embedded in the cavity and solder balls coupling the ports of the ETS to the ports of the die. In some examples, the embedded circuit in the die is a switching power field effect transistor (FET), in other examples, a bulk acoustic wave (BAW) resonator. The circuits embedded in the cavity, in some instances, include a radio frequency (RF) network for the BAW resonator, in other examples, include passive circuit components.

### TECHNICAL FIELD

This disclosure relates to semiconductor devices. More particularly, this disclosure relates to semiconductor devices with a circuit component embedded in a packaging substrate.

### BACKGROUND

A semiconductor device is an electronic component made from semiconductor material with controlled electrical conductivity. The term “semiconductor device” can refer to individual components, such as diodes, transistors, photonic devices and power devices, an integrated circuit (IC) that incorporates multiple electronic components and/or circuits into a single chip, or a semiconductor package. A chip, also known as a microchip, silicon chip, or die, is a piece of semiconductor material, usually silicon, on which the IC is fabricated. The IC can be further encapsulated in a package to form an IC package or semiconductor package. The package includes a packaging substrate, which is a material used to provide structural support and electrical connections. An embedded trace substrate (ETS) is a type of packaging substrate where conductive traces (wires) are embedded within a substrate material rather than being placed on a surface (as in traditional packaging substrates). The die of the semiconductor device is mounted on the package substrate and encapsulated in a molding, such as plastic. The IC package is designed to be mounted on a printed circuit board (PCB) and connected to other components in an electronic system.

A System in Package (SiP) module is a semiconductor packaging technology that integrates multiple components, such as ICs, passive circuit components and sometimes even entire subsystems, into a single package. SiP packaged semiconductor devices are used in various applications, including consumer electronics, internet-of-things (IoT) devices, automotive (e.g., in advanced driver-assistance systems (ADAS)) and medical devices.

### SUMMARY

A first example relates to a semiconductor package that includes a die having an embedded bulk acoustic wave (BAW) resonator and ports on a surface of the die that can be coupled to the BAW resonator. The semiconductor package further includes an embedded trace substrate (ETS) that can underlie the die. The ETS can include embedded components for a radio frequency (RF) network and ports on a surface of the ETS that can be coupled to the RF network. The semiconductor package includes solder balls that can couple the ports of the die to the ports of the ETS.

A second example relates to a semiconductor package that includes a die having an embedded circuit. The die can include ports on a surface of the die that can be coupled to the embedded circuit of the die. The die can include a coreless ETS that can underlie the die. The ETS can include a cavity that can have circuit components embedded in the cavity and ports on a surface of the ETS that can be coupled to the circuit components embedded in the cavity. The semiconductor package can include solder balls that can couple the ports of the ETS to the ports of the die.

A third example relates to a method for fabricating a semiconductor package. The method can include forming a cavity in a coreless ETS, embedding circuit components within the cavity of the ETS, plating a top layer of the ETS with a metal layer and attaching a die with an embedded circuit to the metal layer of the ETS. The circuit components embedded in the ETS can be electrically coupled to the embedded circuit of the die.

### BRIEF DESCRIPTION OF THE DRAWINGS

FIG. 1 illustrates a diagram of an example of a semiconductor device that includes an embedded trace substrate (ETS).

FIG. 2 illustrates a diagram of another example of a semiconductor device that includes an ETS.

FIG. 3A illustrates an example of a Wi-Fi module.

FIG. 3B illustrates an example of an electrical coupling between a bulk acoustic wave (BAW) die and an ETS.

FIG. 4 illustrates a circuit diagram of a BAW resonator and a radio-frequency (RF) network.

FIG. 5A illustrates a diagram of an example of a top-down layout view of an integrated passive filter (IPF) on an ETS substrate.

FIG. 5B illustrates a diagram of a cross-sectional view of the ETS substrate on a 2-layer printed circuit board (PCB).

FIG. 6 illustrates an example of a terminal s-parameter plot.

FIG. 7 illustrates a first stage of a method for forming a semiconductor device.

FIG. 8 illustrates a second stage of a method for forming the semiconductor package.

FIG. 9 illustrates a third stage of a method for forming the semiconductor package.

FIG. 10 illustrates a fourth stage of a method for forming the semiconductor package.

FIG. 11 illustrates a fifth stage of a method for forming the semiconductor package.

FIG. 12 illustrates a sixth stage of a method for forming the semiconductor package.

FIG. 13 illustrates a seventh stage of a method for forming the semiconductor package.

FIG. 14 illustrates a flowchart of an example method for forming a semiconductor device.

### DETAILED DESCRIPTION

This description relates to a semiconductor package with an embedded trace substrate (ETS) having passive circuit components. Semiconductor devices configured with field effect transistors (FETs), such as metal-oxide FETs (MOSFETs) are often used in power applications. The MOSFETs internal to the semiconductor devices are fast switching and generate high current (di/dt) and voltage (dv/dt) transients that can negatively affect a performance of a semiconductor device. A voltage ripple produced by this switching behavior can stress a MOSFET, which decreases a reliability of the MOSFET and increases electromagnetic interference (EMI) emissions. To ensure that power devices meet regulatory standard requirements in an automotive and industrial sector, such as an Electromagnetic Compatibility (EMC) regulatory compliance standard, a circuit, such as a circuit (or passive circuit components) is used to manage EM emissions.

The circuit acts as a filter and acts as a noise minimizer to reduce the amount of EMI emitted by the semiconductor device and protect the MOSFET from stress and reliability issues. In previous approaches, the filter can be placed on a printed circuit board (PCB) on which the semiconductor device is coupled or side by side of a die of the semiconductor device that includes one or more MOSFETs. If the filter is placed on the PCB or adjacent to the die, physical connections to the die create electrical parasitics by increasing a resistance (R) and inductance (L). This increase in R and L can be attributed to additional routing on the PCB and package. For example, in a Small Outline Transistor (SOT) package, the SOT package can include gull-wing leads used for surface mounting. SOT is a type of surface-mount transistor package characterized by its small size and gull-wing leads, which extend out from a package body and then bend downward for soldering to the PCB.

To curtail EMI emission, the filter is situated as physically close to the die as possible. According to one or more examples herein, a semiconductor device is disclosed in which the filter is located within an embedded trace substrate (ETS) of the semiconductor device. Positioning the filter in the ETS rather than outside the semiconductor device (on the PCB) or adjacent to the die results in lower parasitic connectivity and thus improves an EMI performance of the semiconductor device. Furthermore, placing the filter in the substrate packaging (the ETS) allows for vertical integration, does not increase a package area of the semiconductor device, and has no impact on original die-to-package bump routing. Additionally, surface-mount technology (SMT) components can also be integrated into the ETS.

Semiconductor devices are also used in space-constrained applications, such as smartphones, wearables and other portable electronic devices. Semiconductor devices used in space-constrained applications are packaged using electronic packaging technology such as System-in-Package (SiP). SiP packaging is used to ensure that the semiconductor device has a small footprint. One type of semiconductor device (or semiconductor package) is a Wi-Fi module that is commonly used in portable electronic devices to enable these devices to communicate wirelessly. The Wi-Fi module can include multiple dies (or chips) and other circuit components, such as passive elements in a single semiconductor package. For example, the Wi-Fi module can include a bulk acoustic wave (BAW) resonator die, a radio-frequency (RF) signal processing die (for simplicity referred to as a processing die herein) and ETS for coupling the BAW resonator die and the processing die.

In previous approaches, Wi-Fi modules with a radio frequency (RF) network are positioned on the processing die itself. Because the processing die includes the RF network, the processing die has a large die size (e.g., 1.4×1.6 millimeters (mm), for example), which also increases chip manufacturing cost. Examples are disclosed in the present description in which the RF network is offloaded into the ETS. By offloading the RF network to the ETS this reduces the die size of the processing die (e.g., for example to about 0.8×0.6 mm) and thus a footprint of the processing die. Because the footprint of the processing die is reduced this also reduces chip manufacturing cost.

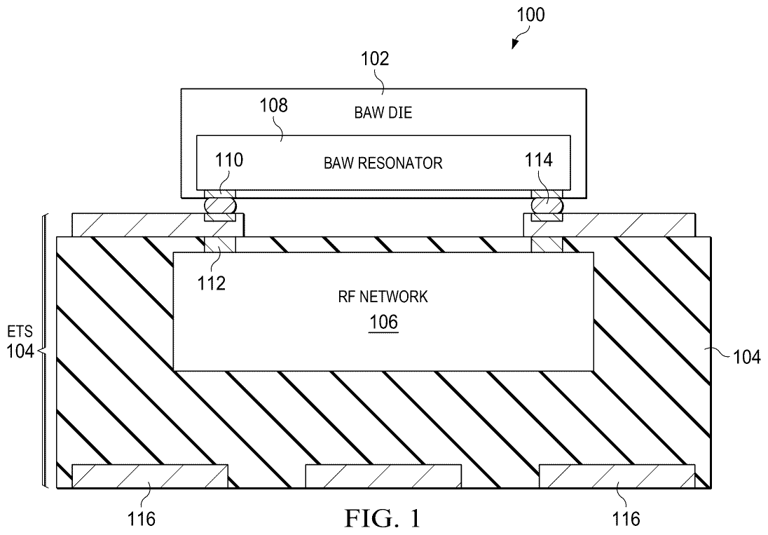

FIG. 1 illustrates a diagram of an example of a semiconductor device 100 that includes a BAW die 102 mounted on an ETS 104. The BAW die 102 and the ETS 104 can be packaged (e.g., with one or more other dies, such as a processing die) to provide the semiconductor device 100. For example, the BAW die 102 and the ETS 104 can be packaged using packaging technology, such as SiP to provide the semiconductor device 100 (a semiconductor package). As shown in FIG. 1, the ETS 104 underlies the BAW die 102. In some examples, the BAW die 102 is attached to the ETS 104 with flip-chip bonding. The ETS 104 can be a coreless ETS or other cored (or coreless) semiconductor packaging substrate. A coreless substrate in semiconductor packaging refers to a substrate design that does not include a central core layer. The ETS 104 includes an RF network 106, which can be implemented as a bandpass filter (e.g., a passive filter).

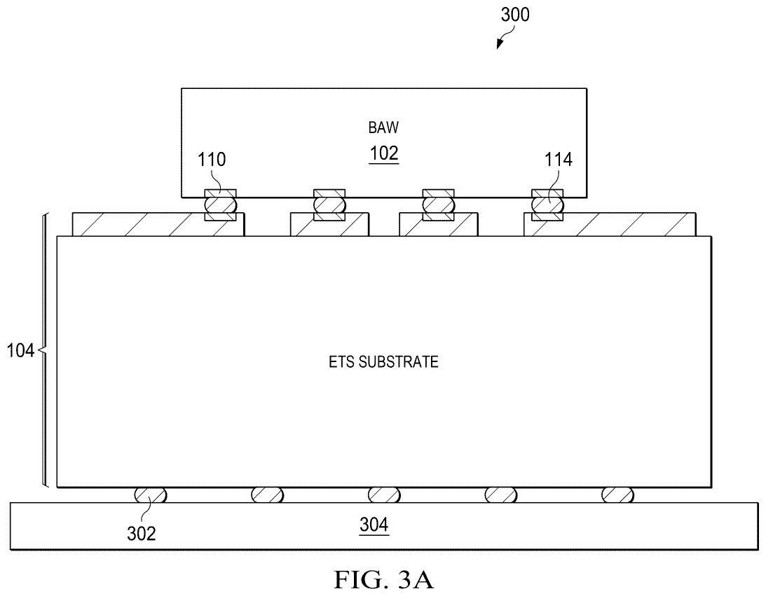

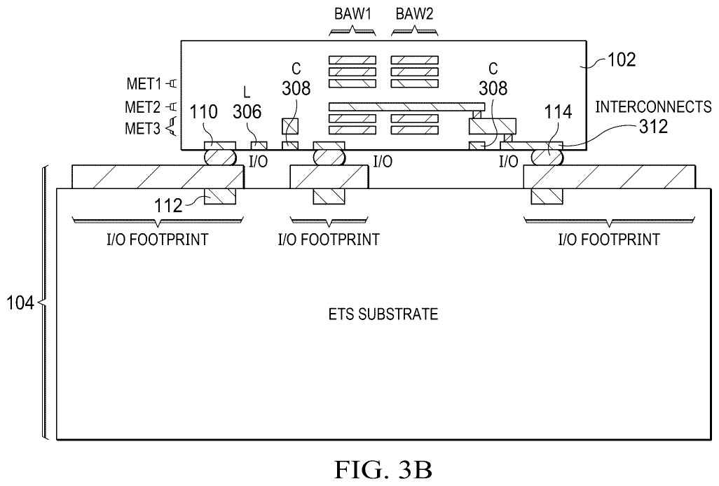

In some examples, the RF network 106 is a first RF network and the BAW die 102 includes a second RF network. The first and second RF networks operate together, effectively forming an integrated RF network. The BAW die 102 includes a BAW resonator 108 and ports 110 on a surface of the BAW die 102. In some examples, the BAW die 102 includes two or more BAW resonators. The RF network 106 and the BAW resonator 108 operate in concert to output an RF signal with a frequency of about 2.4 Gigahertz (GHz) to about 5 GHz, which can be provided in some instances to an RF signal processing die (e.g., see FIG. 3A). The ETS 104 includes ports 112 on a surface of the ETS 104, which are coupled to the RF network 106. Solder balls 114 can be used to couple the ports 110 of the BAW die 102 to the ports 112 of the ETS 104, as shown in FIG. 1. On a surface opposite the ports 112, the ETS 104 can include bottom ports 116, for example, to couple the BAW die 102 to another die, such as an RF signal processing die.

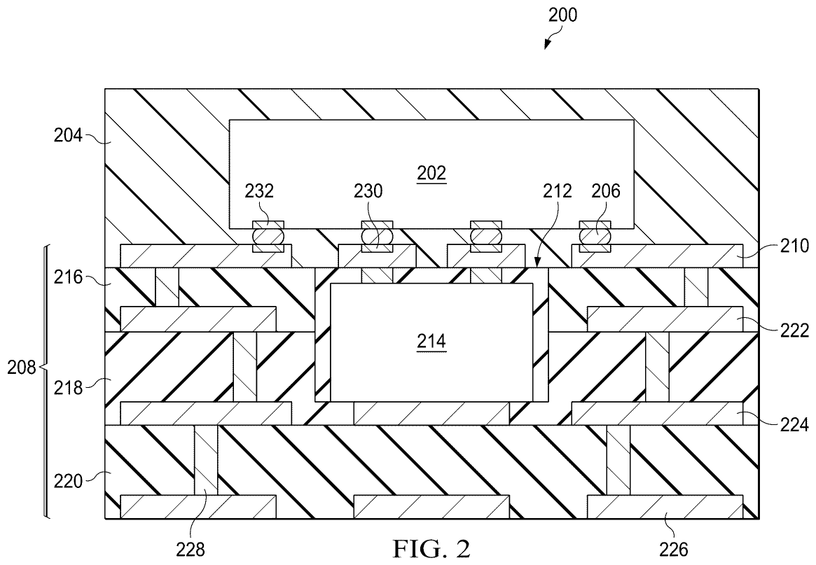

FIG. 2 illustrates a diagram of an example of a semiconductor device 200 with an ETS 208. The ETS 208 can be a coreless ETS. The semiconductor device 200 includes a die 202 that is encapsulated by a mold 204. The semiconductor device 200, in some embodiments, can be implemented as a semiconductor package. The semiconductor device 200 can be packaged according to a packaging technology, such as SiP. The die 202 can include an embedded circuit. The die 202 includes ports 232 on a surface of the die 202, such as the ports 110 of FIG. 1 that are coupled to the embedded circuit of the die 202. In some examples, the embedded circuit of the die includes a switching power FET, such as a MOSFET. The switching power FET can output a switching signal that has a rise time, in some instances, a rise time of 1 microsecond or less. The switching signal can have a switching frequency of about 1 megahertz (MHz), as an example. The switching signal can be delivered using the ETS 208 to a PCB to which the semiconductor device 200 can be mounted.

The ETS 208 includes a top metal layer 210. The top metal layer 210 can include ports 230, such as the ports 112 of FIG. 1. Solder balls 206 can couple the ports 230 of the top metal layer 210 to ports 232 of the die 202. The ETS 208 includes a cavity 212. The cavity 212 includes circuit components 214 that are embedded therein. The top metal layer 210 overlays the cavity 212 and the die 202 is mounted on the top metal layer 210 of the ETS 208 (e.g., coreless ETS), as illustrated in FIG. 2. In the example of FIG. 2, the circuit components 214 are passive circuit components. In examples in which the die 202 is the BAW die 102, the circuit components 214 embedded in the cavity 212 can include the RF network 106 for the BAW resonator 108 of the BAW die 102.

The ETS 208 includes a plurality of dielectric layers 216-220 and embedded metal layers 222-224. The ETS 208 also includes a bottom metal layer 226, which can include bottom ports, such as the bottom ports 116 of FIG. 1. The ETS 208 includes vias 228 (also can be referred to as through-silicon vias (TSVs)). The vias 228 can provide vertical electrical connections between different metal layers of the ETS 208. For example, a subset of the vias 228 can electrically couple a subset of the ports 232 of the die 202 to a corresponding subset of ports 230 of the top metal layer 210.

The die 202 and circuit components 214 are placed on opposite sides of the top metal layer 210 in the semiconductor device 200. This reduces interconnect parasitics and does not affect the solder balls between the die 202 and the ETS 104. Because the cavity 212 in the ETS 104 is positioned beneath the die 202, such a configuration curtails interconnect parasitics and improves the performance and efficiency of the switching power FET.

FIG. 3A illustrates a diagram of an example of a semiconductor device 300 that can be used in RF applications and can be referred to as a Wi-Fi module. The semiconductor device 300 can be implemented, for example, as a semiconductor package and packaged according to a packing technology, such as SiP. The semiconductor device 300 can include the BAW die 102 and the ETS 104, as shown in FIG. 1. The semiconductor device 300 includes solder balls 302 to couple ports of the ETS 104 (e.g., the ports 116, as shown in FIG. 1) to ports of an RF signal processing die 304. The BAW die 102 can be coupled to the ETS 104.

FIG. 3B illustrates an electrical coupling between the BAW die 102 and the ETS 104. In other examples, FIG. 3B illustrates an electrical coupling between a different BAW die and an ETS. In some examples, the BAW die 102 and the ETS 104 can be used as part of the Wi-Fi module. The BAW die 102 includes the ports 110 of FIG. 1, which are input/output (I/O) ports of the BAW die 102. The I/O ports of the BAW die 102 are coupled by the solder balls 114 to the ports 112 of the ETS 104 corresponding to I/O ports of the ETS 104. The ETS 104 has I/O footprints (identified as “I/O footprint” in FIG. 3B), which represent regions where the I/O ports of the ETS 104 are located.

The BAW die 102 can include an inductor 306 and capacitors 308 on its surface, as shown in FIG. 3B. In some examples, the BAW die 102 includes a first BAW resonator (identified as “BAW1” in FIG. 3B) and a second BAW resonator (identified as “BAW2” in FIGS. 3A and 3B). The first and second BAW resonators can be used to filter a particular RF band, such as in an RF application (e.g., Wi-Fi application). Each of the first and second BAW resonators BAW1 and BAW2 include piezoelectric material and electrodes. The BAW die 102 includes a first metal layer MET1, a second metal layer MET2 and a third metal layer MET3. A segment (or portion) of the first metal layer MET1 can be coupled to a top electrode of the first BAW resonator BAW1 (e.g., using vias or metal traces) and another segment of the first metal layer MET1 can be coupled to a top electrode of the second BAW resonator BAW2. Bottom electrodes of the first and second BAW resonators BAW1 and BAW2 can be coupled to the second metal layer MET3, which can be coupled to the third metal layer MET3, as shown in FIG. 3B. The third metal layer MET3 is coupled to a top metal layer 312, which acts as an interconnect metal trace to a corresponding port 110 (I/O port) of the BAW die 102. As disclosed herein, the ETS 104 can include passive circuit components, such as the RF network 106 and the BAW die 102 can include the BAW resonator 108, as shown in FIG. 1.

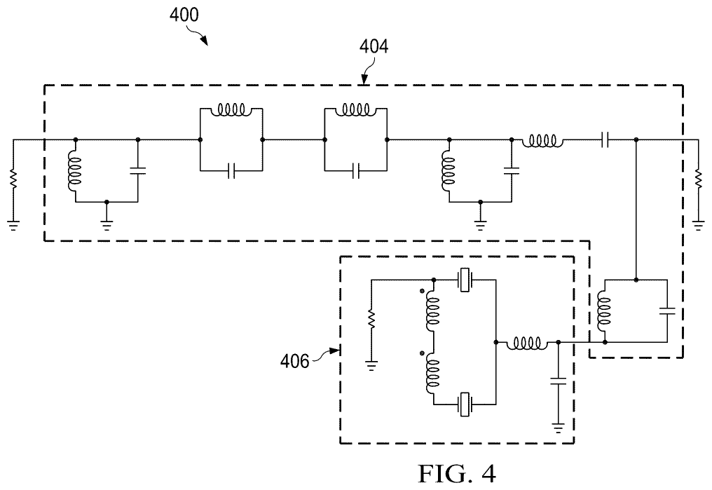

FIG. 4 illustrates a circuit diagram 400 of a BAW resonator 406 and an RF network 404. In some examples, the BAW resonator 406 is the BAW resonator 108 of FIG. 1. The BAW resonator 406 can be implemented as an embedded circuit and be coupled to the ports 110 on the surface of the BAW die 102, as illustrated in FIG. 1. In some examples, the BAW resonator 108 can include the inductor 306 and the capacitors 308, as shown in FIG. 3B. The RF network 404 is an embedded RF network and can include the first RF network 106 of the ETS 104, and the second RF network of the BAW die 102 of FIG. 1, in some instances. The ETS 104 can be implemented as an embedded circuit and be coupled to the ports 112 on the surface of the ETS 104. For example, the RF network 404 and/or the BAW resonator 406 can include capacitors having a capacitance from about 0.05 picofarads (pF) to about 5 pF and inductors having an inductance from about 0.1 nanohenries (nH) to about 10 nH.

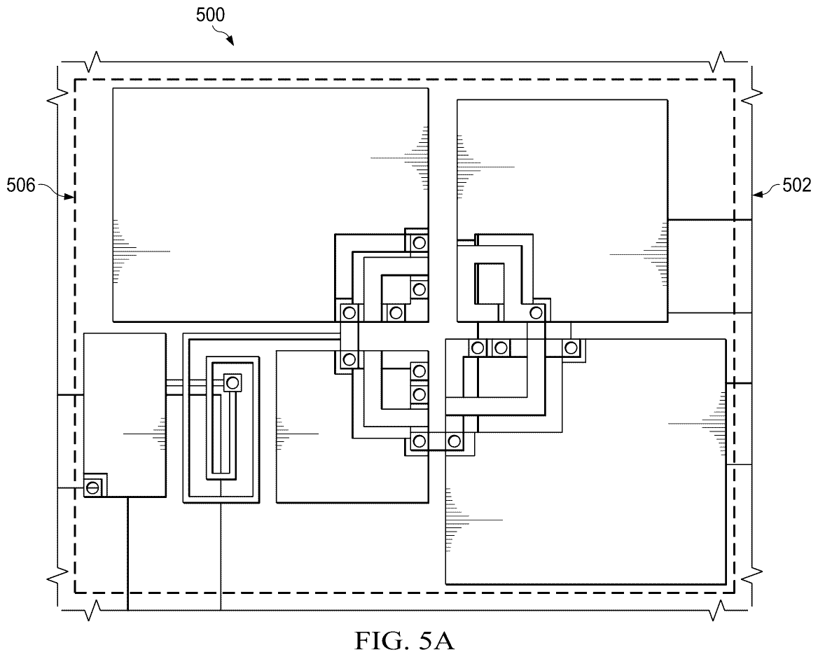

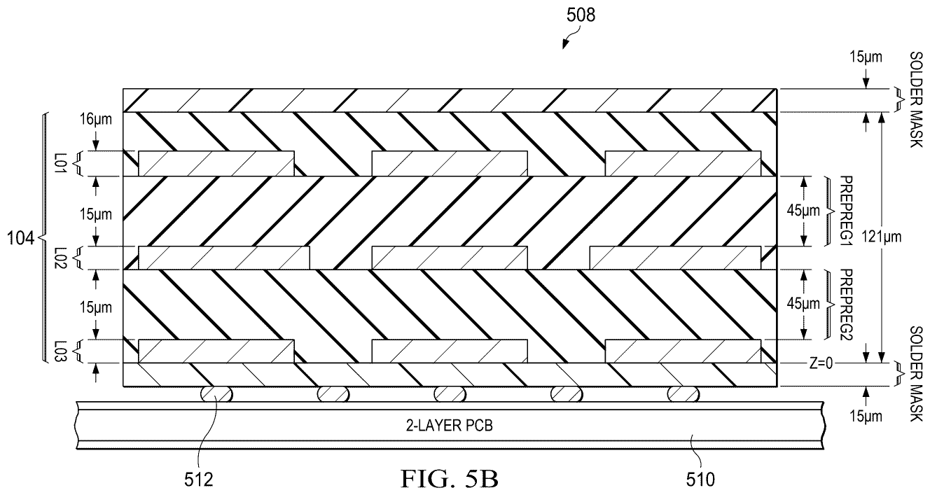

FIG. 5A illustrates a diagram 500 of an example of a top-down layout view of an integrated passive filter (IPF) 506 on an ETS 502, in some examples, corresponding to the ETS 104 of FIG. 1. The IPF 506 can correspond to the RF network 106 of FIG. 1.

In this example, the ETS 502 has a width of about 2 millimeters (mm) and a length of about 2.3 mm. Therefore, a total planar area occupied by the ETS 502 is approximately 4.6 square millimeters (mm²).

FIG. 5B illustrates a diagram 508 of a cross-sectional view of the ETS 502 (the ETS 104), as illustrated in FIG. 5A on a 2-layer PCB 510. In the example of FIG. 5B, the cross-sectional view of the ETS 502 illustrates a structural and material composition of the ETS 104. For example, the ETS 104 can include three metal (e.g., Copper) layers L01, L02 and L03, labeled as having a thickness of about 16 micrometers (μm), 15 μm and 15 μm, respectively. The metal layers L01, L02 and L03 form conductive traces and planes within the ETS 104 and can be used for signal routing, power distribution and/or grounding. The diagram 508 also depicts that the ETS 104 includes insulating prepreg layers Prepreg1 and Prepreg2, each with a thickness of about 45 μm and sandwiched between the metal layers L01, L02 and L03. The prepreg layers Prepreg1 and Prepreg2 are dielectric layers and provide insulation and structural integrity to the ETS 104, bonding the metal layers L01, L02 and L03 together during a lamination process.

In the diagram 508, outermost layers of the ETS 104 on both the top and bottom of the ETS 104 are coated with a solder mask that is about 15 μm thick. The solder mask is used to protect underlying metal traces L01 and L03 from oxidation, contamination and/or potential solder bridges during a soldering process. As shown in the diagram 508, a total height of the ETS 104 from a bottom of a lower solder mask of the ETS 104 (using a Z=0 reference point) to a top of an upper solder mask of the ETS 104 is about 121 μm. The upper solder mask can have openings or pads where the BAW die 102 and RF signal processing die 304 can be coupled. The openings that expose the metal trace L01 on the ETS 104 allow for the IPF 506 to be adhered and coupled (e.g., using solder, conductive adhesive, or other suitable interconnection method) to the ETS 104. The lower mask can have openings or pads as well so that the ETS 104 can be coupled (e.g., mounted to) the 2-layer PCB 510. The openings expose the metal trace L03 on the ETS 104 allowing the ETS 104 to be coupled to the 2-layer PCB 510. Soldering balls 512 can be used to couple the ETS 104 to the 2-layer PCB 510, as shown in FIG. 5B.

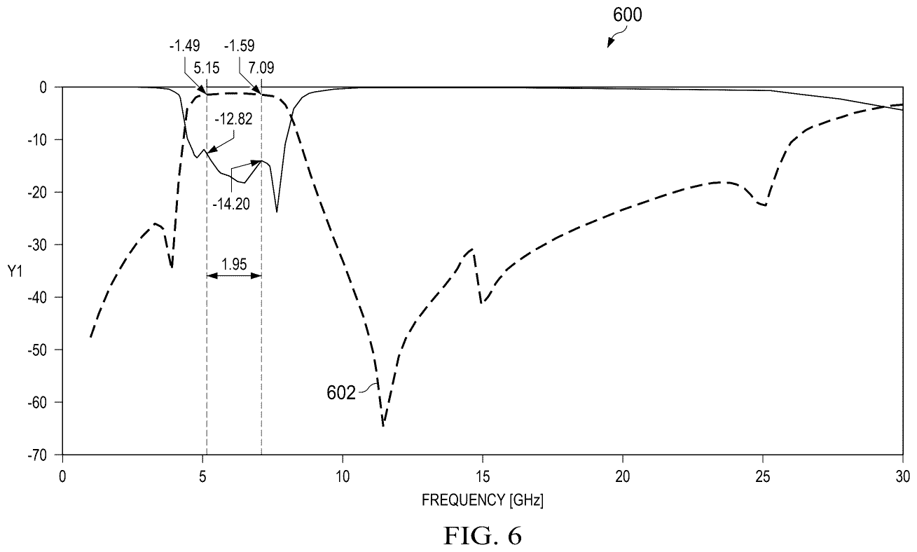

FIG. 6 illustrates an example of an s-parameter plot 600 characterizing a performance of the IPF 506 on the ETS 502, as illustrated in FIG. 5A. The IPF 506 can correspond to an RF filter, such as the RF network 106 of FIG. 1. The IPF 506 can be used to manage RF signals in an RF range, such as those used in Wi-Fi applications (e.g., at about 2.4 GHz to about 5 GHz bands). The S-parameter plot 600 can be used to analyze a frequency response of the IPF 506.

An x-axis of the plot 600 represents a frequency range over which an S-parameter is measured, in GHz, and a y-axis of the plot 600 represents a magnitude of the S-parameter in decibels (dB). The plot 600 illustrates how the IPF 506 behaves over a wide range of frequencies, from around 0 GHz to 30 GHz, covering operational bands of interest for the RF signal processing die 304, such as 2.4 GHz and 5 GHz.

The plot 600 also describes (or measures) how much signal is reflected or transmitted at different frequencies, indicating an efficiency and performance of the IPF 506. The plot 600 includes a frequency response curve 602 illustrating a frequency response of the IPF 506. As illustrated by the plot 600, the IPF 506 effectively filters RF signals across a wide frequency range while allowing the passage of RF signals in Wi-Fi bands.

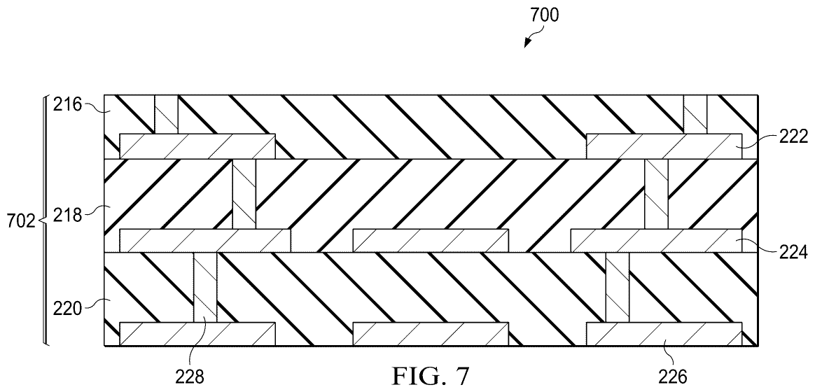

FIGS. 7-13 illustrate stages of a method for fabricating a semiconductor package that includes an ETS, such as the ETS 208, as shown in FIG. 2. As illustrated in FIG. 7, at 700, in a first stage, an ETS 702 is formed, such as the ETS 104 without a top metal layer. As illustrated in FIG. 7, the ETS 702 includes the plurality of dielectric layers 216-220 and embedded metal layers 222-224. The ETS 104 also includes the bottom metal layer 226, which can include bottom ports. The ETS 702 includes vias 228 to provide vertical electrical connections between different metal layers, as shown in FIG. 7.

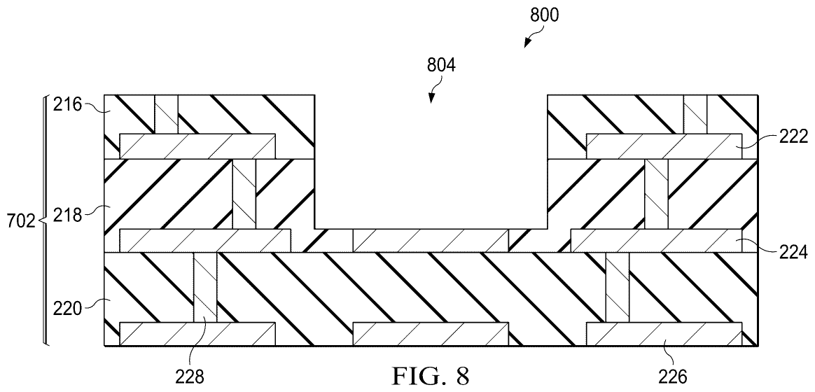

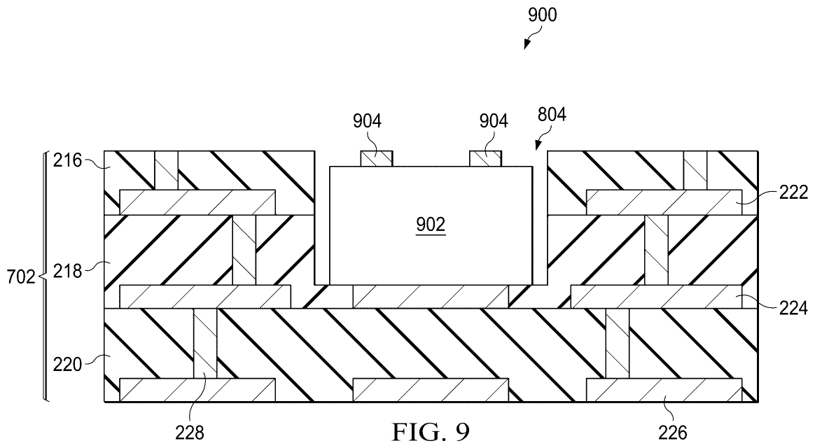

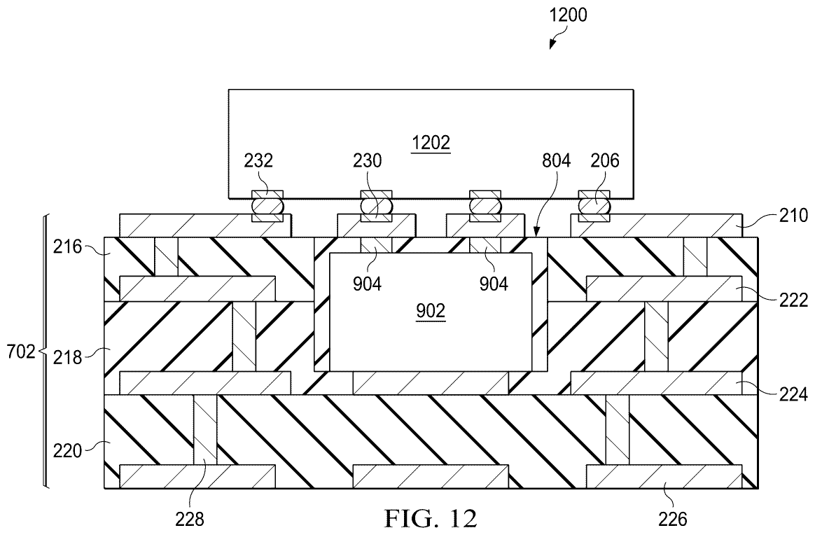

As illustrated in FIG. 8, in a second stage, at 800, a cavity 804 is formed in the ETS 702. The cavity 804 can be formed using laser ablation. Thus, the cavity 804 can be formed by laser application to remove dielectric material from the ETS 702. The cavity 804 can correspond to the cavity 212 of FIG. 2. As illustrated in FIG. 9, in a third stage, at 900, passive circuit components 902 are embedded into the cavity 804. The passive circuit components 902 can correspond to the circuit components 214 of FIG. 2. For example, the passive circuit components 902 can be passively embedded into the ETS 702. Passive embedding refers to an integration of passive electronic components (e.g., capacitors and inductors) into a substrate, such as the ETS 702. Passive embedding is applied at 900 by placing the passive circuit components 902 on one side of a metal layer within the ETS 702, while a die (e.g., a die 1202, as shown in FIG. 12) is placed on an opposite side (e.g., as shown in FIG. 12). This vertical integration allows for a shortest possible interconnect between the die and the passive circuit components 902, which reduces parasitic elements and improves an overall electrical performance of the semiconductor package. By reducing EMI, the semiconductor package can be used in power applications that require a curtailed or low EMI, such as in automotive and industrial power electronic applications. In some examples, at 900, interconnect structures (or vias) 904 are formed on the passive circuit components 902 to enable the passive circuit components 902 to be electrically coupled to the top metal layer that is formed on a top of the ETS 702, as disclosed herein.

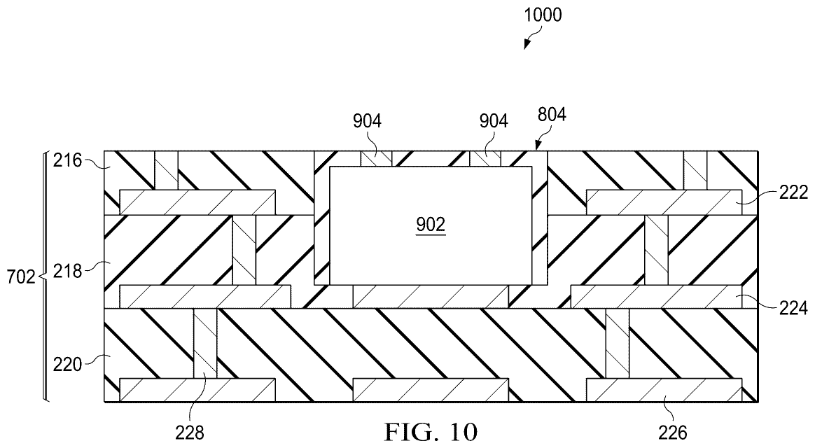

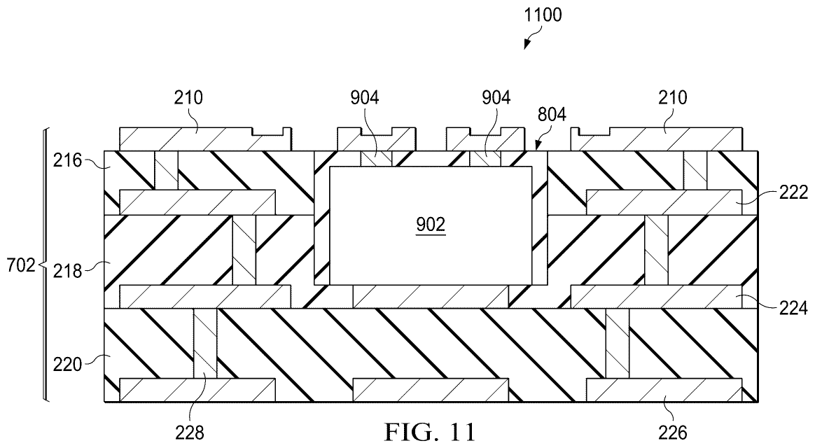

As illustrated in FIG. 10, at 1000, in a fourth stage, gaps or spaces within the ETS 702 around the passive circuit components 902 can be filled. For example, prepreg filling can be used to fill empty portions of the cavity 804 with the passive circuit components 902 embedded therein. As illustrated in FIG. 11, at 1100, in a fifth stage, a top portion of the ETS 702 is plated with a top metal layer, which can be the top metal layer 210 of FIG. 2. In some examples, at 1100, the prepreg filling is grinded to smooth or thin a prepreg material near the top portion of the ETS 702 prior to plating.

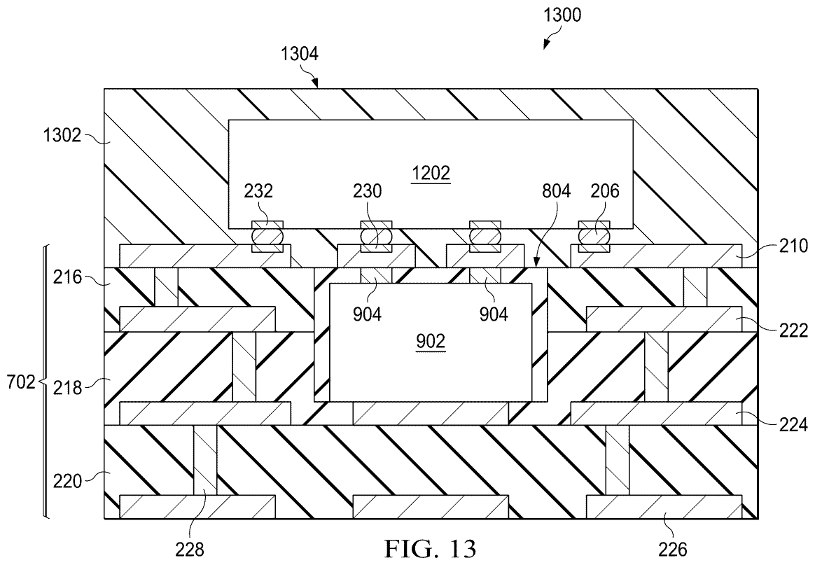

As illustrated in FIG. 12, at 1200, in a sixth stage, a die 1202 with embedded circuit components (e.g., a switching power FET) is attached to the top metal layer 210 of the ETS 702. In some examples, the die 1202 is the die 202 of FIG. 2. By attaching the die 1202 to the ETS 702, the circuit components embedded in the ETS 702 (e.g., the passive circuit components 902) are electrically coupled to the embedded circuit components of the die 1202. For example, the die 1202 can be attached to the ETS 702 using soldering balls (e.g., the soldering balls 206 of FIG. 2). A region of the ETS 702 that includes the cavity 804 and thus the passive circuit components 902 and underlies the die 1202 curtails parasitic effects resulting from operations of the die 1202 (e.g., when the switching power FET is switching). As illustrated in FIG. 13, at 1300, in a seventh stage, the ETS 702 and the attached die 1202 are molded using a molding compound 1302 to provide a semiconductor device 1304, which can correspond to the semiconductor device 200 of FIG. 2.

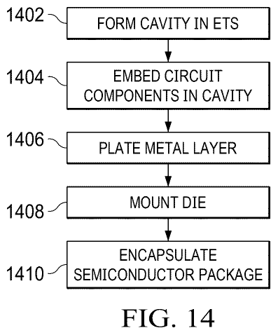

FIG. 14 illustrates a flowchart of an example method 1400 for forming a semiconductor device. The method 1400 could be employed, for example, to form the semiconductor device 100 of FIG. 1, the semiconductor device 200 of FIG. 2, the semiconductor device 300 of FIG. 3A, and/or the semiconductor device 1304 of FIG. 13. At 1402, a cavity (e.g., the cavity 212 of FIG. 2 or the cavity 804 of FIG. 8) is formed in an ETS, such as the ETS 104 of FIG. 1, the ETS 208 of FIG. 2 or the ETS 702 of FIG. 7. The ETS can be a coreless ETS. At 1404, circuit components (e.g., the RF network 106 of FIG. 1, the circuit components 214 of FIG. 2, or the passive circuit components 902 of FIG. 9) are embedded into the cavity. At 1406, a top portion of the ETS is plated with a metal layer (e.g., the top metal layer 210 of FIG. 2). At 1408, a die (e.g., the BAW die 102 of FIG. 1, the die 202 of FIG. 2 or the die 1202 of FIG. 12) is coupled to the metal layer of the ETS. At 1410, the die and the ETS with the embedded circuit components are encapsulated with a molding material to form the semiconductor device (e.g., semiconductor package).

In this description, unless otherwise stated, “about,” “approximately” or “substantially” preceding a parameter means being within +/−10 percent of that parameter. Modifications are possible in the described embodiments and other embodiments are possible, within the scope of the claims.

What is claimed is:

1. A semiconductor package comprising:
a die comprising:
an embedded bulk acoustic wave (BAW) resonator; and
ports on a surface of the die coupled to the BAW resonator;
an embedded trace substrate (ETS) underlying the die, the ETS comprising:
embedded components for a radio frequency (RF) network; and
ports on a surface of the ETS coupled to the RF network; and
solder balls coupling the ports of the die to the ports of the ETS.

2. The semiconductor package of claim 1, wherein the ETS is a coreless substrate.

3. The semiconductor package of claim 1, wherein the RF network comprises a bandpass filter.

4. The semiconductor package of claim 3, wherein the bandpass filter is a passive filter.

5. The semiconductor package of claim 1, wherein the BAW resonator is a first BAW resonator and the die comprises a second BAW resonator.

6. The semiconductor package of claim 1, wherein the RF network of the ETS is a first RF network and the die further comprises a second RF network coupled to the ports of the die.

7. The semiconductor package of claim 1, wherein the BAW resonator and the RF network operate in concert to output an RF signal with a frequency of about 2.4 Gigahertz (GHz) to about 5 GHz.

8. The semiconductor package of claim 1, wherein the die is attached to the ETS with flip-chip bonding.

9. The semiconductor package of claim 1, wherein the die and the ETS are encapsulated with a molding compound.

10. A semiconductor package comprising:
a die having an embedded circuit, the die comprising ports on a surface of the die coupled to the embedded circuit of the die;
a coreless embedded trace substrate (ETS) underlying the die, the ETS comprising:
a cavity having circuit components embedded in the cavity; and
ports on a surface of the ETS coupled to the circuit components embedded in the cavity; and
solder balls coupling the ports of the ETS to the ports of the die.

11. The semiconductor package of claim 10, wherein the circuit components embedded in the cavity are passive circuit components.

12. The semiconductor package of claim 10, wherein the embedded circuit of the die comprises a switching power field effect transistor (FET).

13. The semiconductor package of claim 12, wherein the embedded circuit outputs a switching signal that has a rise time of 1 microsecond or less.

14. The semiconductor package of claim 13, wherein the switching signal has a frequency of about 1 megahertz or more.

15. The semiconductor package of claim 10, wherein the coreless ETS comprises a metal layer overlaying the cavity and the die is mounted on the metal layer.

16. The semiconductor package of claim 10, wherein the coreless ETS comprises a plurality of dielectric layers and a plurality of metal layers.

17. The semiconductor package of claim 10, wherein the circuit embedded in the die comprises a bulk acoustic wave (BAW) resonator and the circuit components embedded in the cavity comprise a radio frequency (RF) network for the BAW resonator.

18. A method of fabricating a semiconductor package, comprising:
forming a cavity in a coreless embedded trace substrate (ETS);
embedding circuit components within the cavity of the ETS;
plating a top layer of the ETS with a metal layer; and
attaching a die with an embedded circuit to the metal layer of the ETS, wherein the circuit components embedded in the ETS are electrically coupled to the embedded circuit of the die.

19. The method of claim 18, wherein a region of the ETS that includes the cavity underlies the die to curtail parasitic effects.

20. The method of claim 18, wherein the forming of the cavity comprises applying laser ablation to remove dielectric material from the ETS.
